(19) United States
(12) Patent Application Publication
(10) Pub. No.: US 2026/0039249 A1
(43) Pub. Date: Feb. 5, 2026

(54) CIRCUIT FOR MITIGATING CURRENT LEAKAGE

(71) Applicant: Renesas Design (UK) Limited, Bourne End (GB)

(72) Inventors: Wallace Alane PIMENTA, Gilbert, AZ (US); Huyhieu NGUYEN, Chandler, AZ (US); Aravind Gopalan MANGUDI, Gilbert, AZ (US); Kyle James WOLLSCHLAGER, Chandler, AZ (US)

(73) Assignee: Renesas Design (UK) Limited, Bourne End (GB)

(21) Appl. No.: 18/792,726

(22) Filed: Aug. 2, 2024

(51) Int. Cl. H03F 1/02; H03F 3/04

(52) U.S. Cl. CPC H03F 1/02; H03F 3/04

(57) ABSTRACT

A current leakage mitigation circuit is provided. The circuit includes a charge storage circuit for receiving a control signal output, and a correction circuit connected to a bottom plate of the charge storage device. The control signal is output by an amplifier circuit connected to the current leakage mitigation circuit. The correction circuit samples the control signal, applies a filter to the control signal for to extracting a predefined frequency component, amplifies the filtered control signal, and applies the amplified control signal to the bottom plate of the current storage device.

### FIELD

The present disclosure relates to a circuit configured to mitigate current leakage.

### BACKGROUND

It is well known that analog circuits and systems that have a defined frequency response make use of passive elements, such as integrated resistors and capacitors, to place poles and zeros at desired frequencies. For example, some circuits have very high output impedance such that any leakage current resulting from passive elements such as capacitors will have a disproportionately large effect on output voltage. Due to the low transconductance values of circuits such as error circuits, significant input referred offset error is produced as a result of the effect of the passive elements on the output voltage.

A widely used example of a circuit that uses a defined frequency response is the conventional Gm-amplifier, as illustrated by FIG. 1, wherein an error voltage at an input generates an error current in the output. The frequency response of the circuit is determined by the passive elements on its output.

FIG. 1 shows an amplifier device Gm which output a signal Vcontrol. Connected to the amplifier device Gm are passive elements, such as capacitor C and resistor R. For example, resistor R is connected between the amplifier device Gm and the capacitor C. The capacitor C serves the purpose of creating the dominant pole and zero of the frequency response, shaping the frequency.

Capacitors such as capacitor C are typically constructed from 5V Gate Oxide MOS devices, of which a major drawback is the required silicon area. The required large silicon area of these devices results in increased product costs. An alternative is to use denser, lower voltage gate oxide capacitors, however these capacitors exhibit higher leakage and introduce inaccuracies, which makes them undesirable in high precision analog applications.

A further disadvantage of these circuits is that some types of capacitors which may be used have a voltage dependence. This voltage dependence makes the frequency response of these circuits vary with respect to the common output mode voltage.

For example, in switching converter circuits, the output of amplifiers is the control signal of the loop for the converter. This signal varies depending on the duty cycle (which itself varies with different supply voltages, output voltages, loads and the like). The frequency shaping capacitor (or, in some examples, a plurality of capacitors) is connected to the output of the amplifier such that, as the voltage across the capacitor dynamically changes based on the wide operating conditions, it becomes increasingly difficult to predict and stabilize the frequency response of the switching converter for all conditions.

For all of these reasons, it is desirable to provide a circuit that mitigates current leakage in passive components.

### SUMMARY

It is desirable to provide a circuit for mitigating current leakage.

According to a first aspect of the disclosure, there is provided a current leakage mitigation circuit comprising:
a charge storage circuit configured to receive a control signal output, wherein the control signal is output by an amplifier circuit connected to the current leakage mitigation circuit; and
a correction circuit connected to a bottom plate of the charge storage device;
wherein the correction circuit is configured to:
sample the control signal;
apply a filter to the control signal, wherein the filter is configured to extract a predefined frequency component;
amplify the filtered control signal; and
apply the amplified control signal to the bottom plate of the current storage device.

Optionally, the charge storage circuit comprises a capacitor.

Optionally, the correction circuit comprises:
a filter circuit configured to apply a filter to the control signal; and
a buffer amplifier connected to the charge storage circuit configured to amplify the filtered control signal and apply the amplified control signal to the bottom plate of the current storage device.

Optionally, the buffer amplifier is connected to a bottom plate of the capacitor of the charge storage circuit.

Optionally, the filtered control signal is amplified by the buffer amplifier by applying a gain value to the control signal.

Optionally, the gain value is a unity gain value or an arbitrary value.

Optionally, the filter circuit comprises a low-pass filter.

Optionally, the filter circuit comprises a resistor and a capacitor.

Optionally, the filter circuit comprises an amplifier device and a capacitor.

Optionally, the capacitor is connected between the output of the amplifier circuit and ground.

Optionally, the low-pass filter is one of a passive, active, or digital filter.

Optionally, the charge storage circuit comprises a plurality of capacitors.

Optionally, the capacitor and/or plurality of capacitors are thin oxide capacitors.

Optionally, the capacitor and/or the plurality of capacitors are thick oxide capacitors.

Optionally, the amplifier circuit comprises an amplifier device; wherein the amplifier device is a transconductance amplifier, an EA amplifier, an error amplifier, or a GM amplifier.

Optionally, the circuit further comprises a PMOS or NMOS device configured to generate a fixed voltage to be applied to the charge storage circuit; wherein the PMOS or NMOS device is connected to the correction circuit; and wherein the correction circuit applies a fixed current to the PMOS or NMOS device.

Optionally, the circuit is part of a DC-DC converter.

Optionally, the charge storage circuit further comprises a resistor.

According to a second aspect of the disclosure, a method of mitigating current leakage in a circuit, the method comprising:
sampling, by a correction circuit, a control signal output by an amplifier circuit connected to the current leakage mitigation circuit,
applying, by the correction circuit, a filter to the control signal, wherein the filter is configured to extract a predefined frequency component of the control signal;
amplifying, by the correction circuit, the filtered control signal; and
applying, by the correction circuit, the amplified control signal to a charge storage circuit,
wherein the charge storage circuit is connected between the amplifier circuit and the correction circuit.

### BRIEF DESCRIPTION OF THE DRAWINGS

The disclosure is described in further detail below by way of example and with reference to the accompanying drawings, in which:

FIG. 1 shows a circuit diagram illustrating the prior art;

FIG. 2 shows a block diagram representing a circuit for mitigating current leakage;

FIG. 3 shows a block diagram representing a circuit layout for a circuit for mitigating current leakage;

FIG. 4 shows a circuit diagram representing an example circuit for mitigating current leakage;

FIG. 5 shows a circuit diagram according to a first example;

FIG. 6 shows a circuit diagram according to a second example;

FIG. 7 shows a circuit diagram according to a third example;

FIG. 8 shows a circuit diagram according to a fourth example;

FIG. 9A shows a circuit diagram representing an example of a prior art circuit;

FIG. 9B shows a circuit diagram according to an embodiment of the invention; and

FIG. 10 shows a graph illustrating a comparison of leakage current against bias voltage for two circuits.

### DETAILED DESCRIPTION

In a typical operational transconductance amplifier circuit, an error voltage at the input of the amplifier (for example, an EA amplifier, or an error amplifier) generates an error current in the output of the amplifier, wherein the frequency response of the circuit is determined by the passive elements connected to the output. For example, the passive elements may include one or more capacitors, wherein the capacitors may have the purpose of providing higher frequency response shaping and staggering elements. The capacitors may be MOS oxide capacitors, metallization capacitors, or the like.

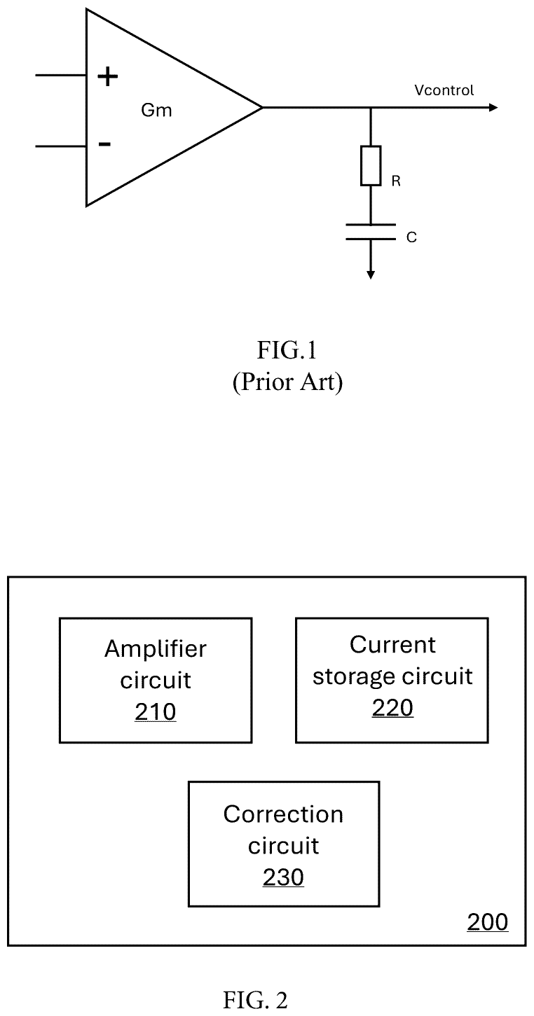

For example, referring to FIG. 1, capacitor C creates the dominant pole and zero for the circuit, shaping the frequency response. FIG. 1 shows an amplifier device Gm which output a signal Vcontrol. Connected to the amplifier device Gm are the passive elements, capacitor C and resistor R. The capacitor C serves the purpose of creating the dominant pole and zero of the frequency response, shaping the frequency.

In the circuit of FIG. 1, and considering the output impedance of the amplifier device as Rout, the dominant pole and zero can be approximately calculated by equations 1 and 2, respectively, as follows:

$${f}_{p} ∼ \frac{1}{2 π {R}_{OUT} {C}_{CC}} \qquad ( 1 )$$

$${f}_{z} ∼ \frac{1}{2 π {R}_{CC} {C}_{CC}} \qquad ( 2 )$$

As can be seen from equations 1 and 2, the frequencies, fp (pole) and fz (zero), are inversely proportional to the capacitance value.

Additionally, it is very well known, in integrated circuits, to use MOS (Metal Oxide Semiconductor) capacitors (either thin or thick oxide) in circuits such as that of FIG. 1, wherein the MOS capacitors present a voltage dependency on the capacitance value. Thus, depending on the circuit bias operating point, dominant poles and zeros may change, making it harder to compensate for the capacitor's effect on frequency response.

When using thin oxide MOS capacitors in most advanced technology nodes, there is a higher direct current (DC) leakage for said integrated capacitors. As technological nodes advance, active and passive elements change their main characteristics based on technology constraints. Specifically, as the technology gets smaller and more dense, oxides such as gate oxide, used in capacitors, get thinner and more prone to current leakage.

This current leakage can lead to a higher, not accounted for, offset voltage at the input of the amplifier device Gm. This, in turn, reduces the accuracy of the system in which the circuit is being used, because the unexpected leakage in the output creates a differential voltage at the input, as can be seen in equations 3 and 4 below:

$$Δ {i}_{out} = Gm Δ {V}_{in} \qquad ( 3 )$$

$$Δ {V}_{in} = \frac{Δ {i}_{out}}{Gm} \qquad ( 4 )$$

Thus, to make use of current technological advances and to more efficiently make use of circuit area, the use of leaky capacitors becomes necessary. Thus, it is also necessary to address the current leakage because of the differential voltage it creates.

A way to address the current leakage is to make the DC bias voltage of the capacitor (or other charge storage device) zero (or near zero). This is because this allows the capacitor to perform as if there were no current leakage, regulating the voltage across the capacitor and mitigating the current leakage.

FIG. 2 is a block diagram representing a circuit 200 for mitigating current leakage. The circuit 200 comprises an amplifier circuit 210, a charge storage circuit 220, and a correction circuit 230.

The amplifier circuit 210 may be an operational amplifier device. For example, the amplifier circuit 210 may be any amplifier circuit comprising a compensation element that would eventually be prone to current leakage issues; for example, an operational transconductance (or Gm) amplifier, an error amplifier, an EA amplifier or the like. The amplifier circuit receives an input voltage at an input port and outputs a control signal, Vcontrol, at an output port. The control signal is a signal that comprises information used to control a loop of the circuit being sampled. The control signal varies over time with respect to a reference value (for example a target value) due to variations in variables such as load, temperature, aging, noise and the like. Thus, the control voltage changes to reflect the variation in the variables, wherein the variables typically include feedback signal and a reference value. The control signal may include frequency response.

In more detail, the control signal, Vcontrol, is an error signal (for example, a voltage) which represents the difference between the reference value and the signal being controlled (for example, the signal being controlled may be an output voltage such as a buck converter output voltage). The strength of the control signal is based on a difference between the signal being controlled and the reference value. For example, the larger the difference between the signal being controlled and the reference value, the stronger the control signal, which in turn demands a greater reaction from the loop of the circuit being sampled. For example, the reaction may be increasing a duty-cycle of the system.

The charge storage circuit 220 comprises passive elements such as capacitors, resistors and the like. For example, the charge storage circuit 220 may comprise a resistor and a capacitor. In another example, the charge storage circuit 220 may additionally comprise a plurality of capacitors.

The correction circuit 230 is configured to sample (for example, by copying and/or modifying) the control signal and apply the sampled control signal to the charge storage circuit 220 in order to reduce the effect of current leakage in the passive elements (for example, current leakage of one or more capacitors connected between the amplifier circuit and ground) of the charge storage circuit 220 on the frequency response of the amplifier circuit 210.

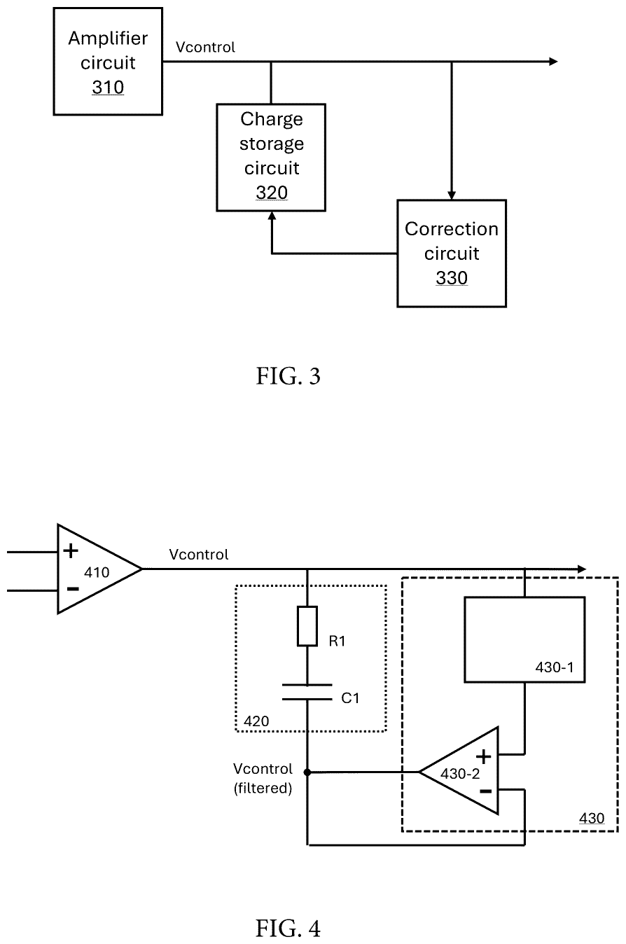

FIG. 3 is a block diagram illustrating a signal flow in the circuit for mitigating current leakage. For example, the circuit represented in FIG. 3 may be the same as circuit 200 described by reference to FIG. 2.

FIG. 3 shows amplifier circuit 310 (for example, amplifier circuit 310 may be the same as amplifier circuit 210) outputting a control signal, Vcontrol, which is sampled by correction circuit 330. The sampled signal is then transmitted to the charge storage circuit 320. The charge storage circuit 320 is connected between the amplifier circuit 310 and correction circuit 330.

The charge storage circuit 320 may comprise a capacitor, wherein a top plate of the capacitor is connected to the output port of the amplifier circuit 310 and a bottom plate of the capacitor is connected to the correction circuit 330. The sampled control signal may be applied to a bottom plate of the capacitor.

In doing so, the frequency response of the signal may be affected because similar voltages are being applied simultaneously to both plates of the capacitor (for example, the top plate is receiving a voltage output from the amplifier circuit, and the bottom plate is receiving the sampled voltage from the correction circuit). Thus, it is desirable to not only reduce (or eliminate) current leakage, but to leave the frequency response unaffected while doing so.

In light of this, a frequency component of the control signal may be sampled (for example, a low frequency component) by the correction circuit 330. This sampled control is then transmitted to the charge storage circuit 320. Thus, the capacitor plate will see a DC voltage equal to the low frequency component of the control voltage such that it approximates zero DC voltage in a steady state condition. This means that, in steady state conditions where the control signal, Vcontrol, does not vary significantly (for example, where the control signal varies only in a high frequency component, such as because of noise), the voltage applied by the correction circuit 330 to a bottom plate of the capacitor of the charge storage circuit 320 is equal (on average) to a voltage applied to a top plate of the capacitor, which results in the capacitor experiencing a near zero DC bias voltage, where current leakage is negligible. In other examples, the DC voltage in the steady state condition may not be zero, it may be any desired value in the case that a fixed gain amplifier is used. For example, in the case that the capacitor is a MOS capacitor, the capacitance curve of the capacitor is not constant over the bias voltage applied to it. As such, in normal use, higher capacitance values may result if the DC bias voltage applied is higher than OV which may effectively reduce the area used for the same capacitance needed.

The control signal may be sampled and amplified by a buffer amplifier (of the correction circuit 330) and may be sampled and filtered to extract the low frequency component of the control signal using a filter circuit of the correction circuit 330. The buffer amplifier and the filter circuit may be part of the correction circuit 330. This is described in more detail with reference to FIG. 4.

FIG. 4 is a circuit diagram illustrating an example circuit layout. The circuit diagram may be representative of a circuit such as the circuits described by reference to FIG. 2 and/or FIG. 3.

The circuit diagram of FIG. 4 comprises an amplifier device 410 (an example of the amplifier circuits described by reference to FIGS. 2 and 3), a charge storage circuit 420 which comprises a resistor R1 and a capacitor C1, a filter circuit 430-1, and a buffer amplifier 430-2, wherein the filter circuit 430-1 and the buffer amplifier 430-2 comprise a correction circuit 430 (wherein the correction circuit 430 may be a correction circuit such as correction circuit 230 or 330 described by reference to FIGS. 2 and 3, respectively).

In some examples, the charge storage circuit 420 may comprise further components, in addition to the resistor R1 and the capacitor C1. For example, the charge storage circuit 420 may include a plurality of capacitors. It should be understood that the charge storage circuit 420 depicted in FIG. 4 is intended as an example and is not intended to be limiting.

The filter circuit 430-1 is configured to sample the control signal and extract a predefined frequency component (for example, a low frequency component such as that the resulting output of a low-pass filter). For example, the filter circuit 430-1 may be a low pass filter, a passive filter (comprising only resistors and capacitors, for example), an active filter (comprising amplifier devices, resistors, MOS elements, capacitors or the like) or the like.

The buffer amplifier 430-2 is then configured to amplify the control signal. The buffer amplifier 430-2 may be an amplifier device such as a unity gain amplifier which is configured to copy the filtered control signal received from the filter circuit 430-1 and transform the filtered control signal by changing its impedance. This allows the circuit to drive more challenging loads. For example. if the circuit has a large capacitance value, the circuit may be challenging to drive and may affect the frequency response of the circuit if a simple resistor-capacitor low-pass filter is used. The buffer amplifier 430-2 preserves the frequency response while being able to supply the capacitor C1 with current necessary to change the voltage applied to the bottom plate of the capacitor C1.

Thus, the leakage of the capacitor C1 and the varying Common Mode (CM) voltage of the signal control can be checked. For example, if capacitor C1 is a 100 pF capacitor, and the CM voltage is 1.2V, the leakage current of capacitor C1 may reach 100 nA. This current leakage when using an amplifier device with typical transconductance values of 1/100 k or 1/500 k can lead to several millivolts (mV) of error at the input of the amplifier device. Using the approach described above, by sampling, filtering, and amplifying the control signal before applying the resulting signal to the bottom plate of the capacitor C1, this current leakage can be mitigated, thus also mitigating the error voltage at the input of the amplifier device.

As will now be discussed, the filter circuit 430-1 may be implemented in various ways, using several different types of circuits.

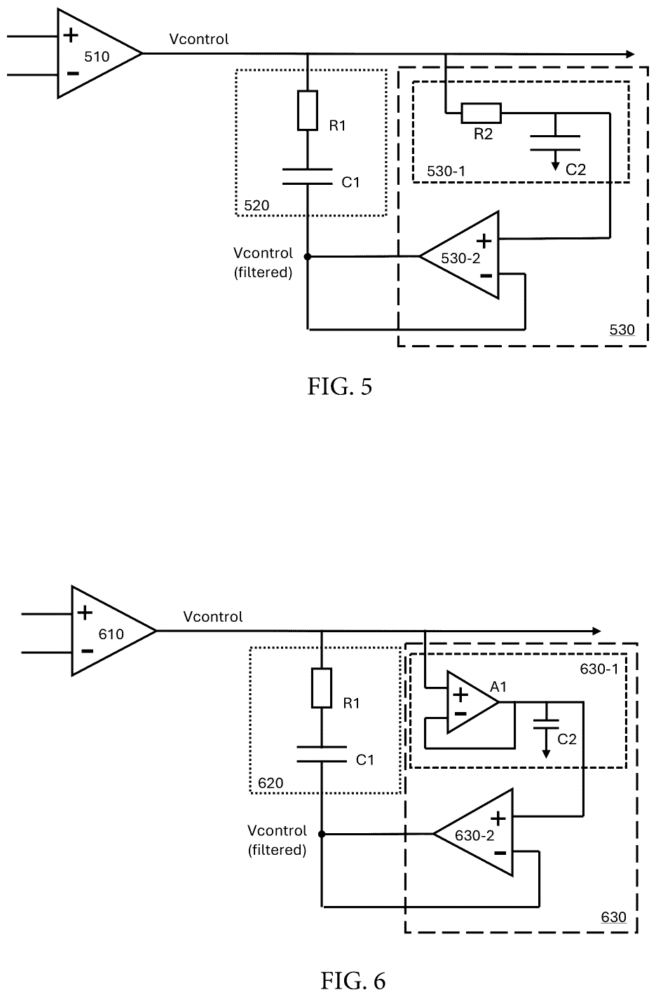

FIG. 5 shows a circuit diagram according to a first example of the invention, a specific example of the circuits described by reference to FIGS. 2-4.

The filter circuit 530-1 comprises, in the first example, a resistor R2 and a capacitor C2, wherein a bottom plate of the capacitor C2 is connected to ground, and wherein the resistor R2 and the capacitor C2 act as a low pass filter (also known as an RC low-pass filter), extracting a low frequency component of the signal control (thereby generating, or creating, a filtered control signal) and sending the filtered control signal to the buffer amplifier 530-2. As described above, the buffer amplifier 530-2 then amplifies the filtered control signal and applies the amplified, filtered control signal to the bottom plate of capacitor C1.

In other examples, it may be desirable to implement an amplifier to act as filter circuit 530-1, as will now be described by reference to FIG. 6.

FIG. 6 shows a circuit diagram according to a second example of the invention, a specific example of the circuits described by reference to FIGS. 2-4.

The filter circuit 630-1 of correction circuit 630 (wherein correction circuit 630 may be used in any of the examples described by reference to FIGS. 2-5, for example, in place of any of correction circuits 230 to 530) comprises, in the second example, an amplifier device Al and capacitor C2, wherein a bottom plate of the capacitor C2 is connected to ground. The amplifier device A1 may be any active circuit capable of emulating a resistor.

Using the amplifier device A1 to implement the filtering of the signal control (that is, implementing the amplifier device A1 as part of the filter circuit 630-1) prevents interference of additional passive elements (such as resistor R2 and capacitor C2 of FIG. 5) with the frequency response or accuracy. For example, using the amplifier device A1 prevents loading to the control node. Additionally or alternatively, the output impedance of the amplifier device A1 may be used to determine a filter cut-off frequency.

In more detail, R2 and C2 act as an effective “load” to the amplifier 610 and can affect the frequency response. However, their values are known so they can be taken into account to achieve a desired frequency from the circuit. Generally, the values, such as capacitance and resistance, are very different when comparing C1 and C2 and R1 and R2 (for example, the resistance of R1 and capacitance of C1 may be comparatively much larger than those of R2 and C2, respectively), and the effective frequency response tends towards the R1 and C1 elements. By applying an amplifier before (which typically has a much smaller capacitance at the output in comparison to C2 or C1), it can be ensured that the R2 and C2 values do not affect the shaping of the frequency response imposed by R1 and C1, irrespective of the values of R2 and C2.

This example may be implemented in ways including, but not limited to: a unity gain amplifier positioned at the output of control; and setting a compensation of the amplifier to low frequency. For example, adding the unity gain amplifier has the effect of preventing a loading effect, which may be critical in some applications. As described in more detail by reference to FIG. 4, the amplifier device comprises internal compensation elements (such as resistors and capacitors) which may be used to set a low pass frequency. That is, an amplifier device with a very low frequency bandwidth may be used to yield the same results as using R2 and C2 to provide low pass filtering.

The combination of filtering (with or without the use of an additional amplifier) and the buffer may optionally be a unity gain circuit (wherein a voltage applied to a non-inverting port of an amplifier is the same as a voltage output by the output port of the amplifier). It should be understood that the use of unity gain circuits is not necessary for the above-described implementations. Rather, any desired gain value might be applied, according to the needs of the application.

In more detail, a fixed or variable gain circuit may be used to apply a non-zero desired DC bias voltage in the capacitor C1. For example, when using a bias dependent capacitor, optimal capacitance values may occur at higher voltages and, as such, it may be desirable to apply a non-zero DC bias voltage to the capacitor.

Alternatively, if current leakage is not an issue in a given application, the above-described circuit implementation may nonetheless be used to optimize the capacitance value of the capacitor C1 (or its equivalent) and to increase the efficiency of the use of silicon area (for example, by reducing silicon area).

As will now be discussed, the above-described circuits may be used in various applications.

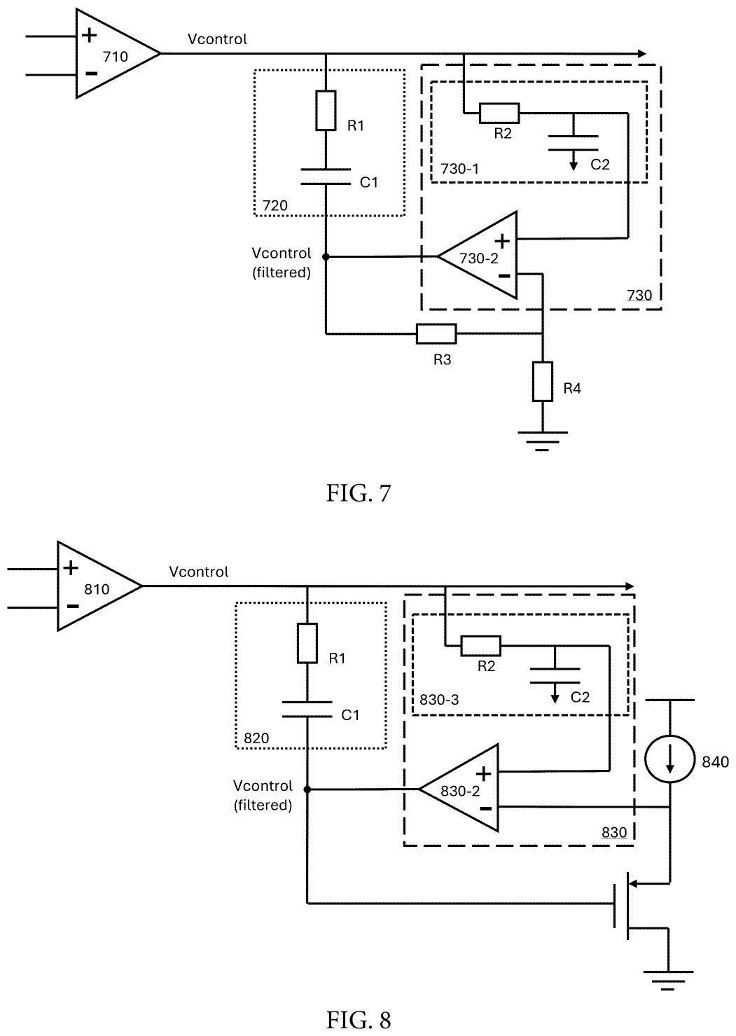

FIG. 7 shows a circuit diagram representing an example application of any of the circuits described by reference to FIGS. 2-6.

In the example illustrated in FIG. 7, two resistors, R3 and R4, are connected between a negative port of the buffer amplifier 730-2 and a bottom plate of capacitor C1, wherein resistor R4 is connected between resistor R3 and ground.

Thus, an absolute DC voltage difference is applied in the capacitor C2. This allows capacitance to be maximized and silicon area to be reduced, thus also reducing the relative cost for producing the circuits.

FIG. 8 shows a circuit diagram representing another example application of any of the circuits described by reference to FIGS. 2-6.

In the example illustrated in FIG. 8, a PMOS device 840 (a p-channel metal-oxide semiconductor, for example) may be connected between a negative port of the buffer amplifier 830-2 and the bottom plate of the capacitor C2.

The PMOS device 840 may be used to generate a fixed voltage by applying a fixed current, by the buffer amplifier 830-2, to a VGS of the PMOS device 840. The VGS may then be applied as a fixed voltage across the capacitor C2. By increasing the capacitance per unit area of the circuit, because the MOS capacitance curve is not constant, density will be higher at slightly voltage biasing.

Although FIGS. 7 and 8 show a filter circuit according to the implementation of FIG. 5, it should be understood that any example filter circuit would be suitable. For example, the filter circuit 630-1 described by reference to FIG. 6 may be used in the circuits of FIGS. 7 and 8 in place of the illustrated filter circuits. That is, any of the correction circuits 230 to 630 may be combined with the circuits of FIGS. 7 and 8. In fact, any type of low pass filter could be used. For example, a cascade of RC filters may be used, or active filters.

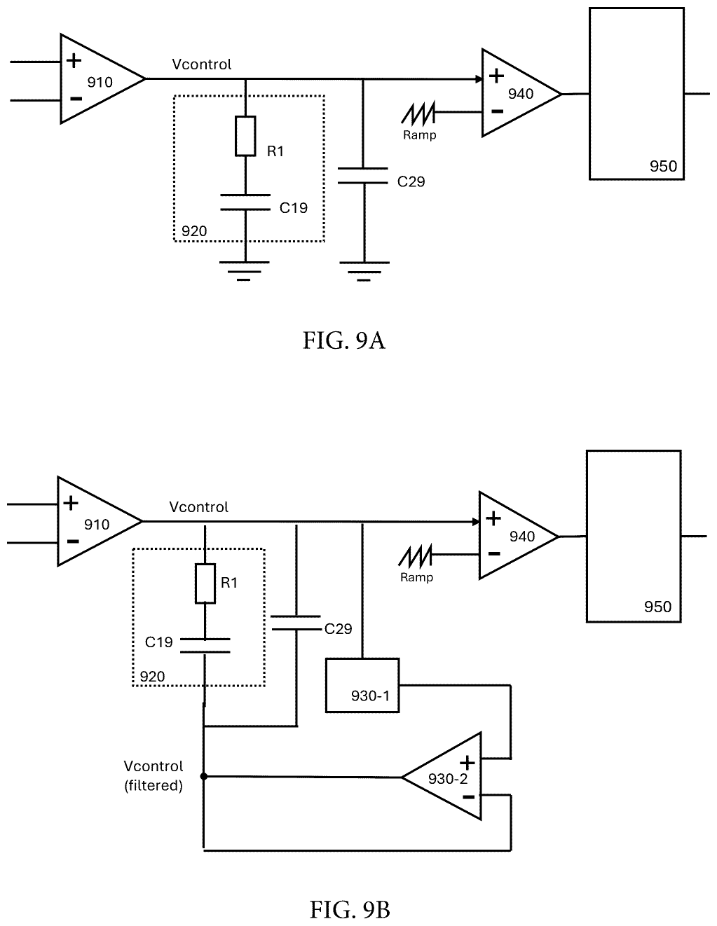

FIG. 9A shows a circuit diagram according to the prior art, for use in an application wherein a low voltage capacitor is needed where the dynamic range itself (that is, the voltage experienced by the component or the circuit; for example, in this case, the dynamic range may be the total voltage experienced by the capacitor of the charge storage circuit) surpasses the capacitor voltage rate and/or a low bias voltage is needed for de-rating or leakage control purposes. FIG. 9B illustrates an improved circuit diagram according to the invention.

FIGS. 9A and 9B each show a circuit diagram representing a control circuit for a DC-DC converter, specifically a Buck converter. It should be understood that the following could apply to any DC-DC converter and the Buck converter of FIGS. 9A and 9B is used purely exemplary. The circuit comprises an amplifier device 910 (such as any of the amplifier devices described by reference to FIGS. 2-4), a Pulse Width Modulation (PWM) comparator 940, compensation components (such as resistors and capacitors), a logic block 950, power Field-Effect Transistors (FETs) (not shown), and the like.

The circuit of FIG. 9A requires a capacitor, C19 or C29, that can withstand the total dynamic range voltage of the circuit and also has insignificant current leakage. However, by using a low voltage capacitor, both of these problems arise. As such, the benefit of having a smaller area cannot be easily achieved.

This problem is solved by implementing the circuit shown in FIG. 9B. The circuit of FIG. 9B adds a correction circuit (such as any of correction circuits 230, 330, 430, 530, 630, 730, or 830 of FIGS. 2-8). It should be understood that although the example shows a correction circuit according to correction circuit 430 described by reference to FIG. 4, any of the correction circuits described by reference to any of FIGS. 2-8 may be implemented in the circuit of FIG. 9B.

By implementing the correction circuit, a frequency component (for example, a low frequency component) of the control signal is sampled, filtered and amplified (for example, as described by reference to FIGS. 2-4) and the filtered, amplified control signal is applied to a bottom plate of capacitor C19 and capacitor C29. Thus, the capacitors C19 and C29 are set with a known DC bias voltage, allowing smaller density capacitors to be used.

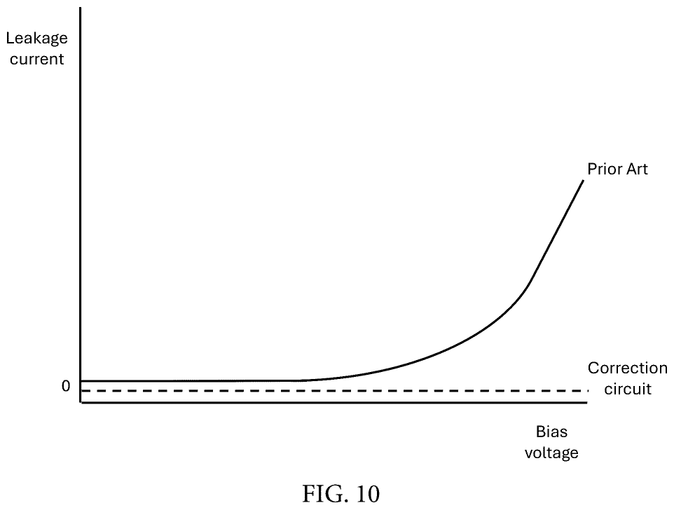

FIG. 10 further illustrates the technical effect of the correction circuits described by reference to FIGS. 2-9, showing a graph illustrating a comparison of current leakage in circuits of the prior art and in circuits implementing the correction circuits of the invention.

The graph of FIG. 10 shows current leakage over DC bias voltage. It can clearly be seen that at voltage V, the current leakage of capacitors in the prior art circuits begins to increase exponentially, starting at near zero. In comparison, the current leakage of the capacitors in the circuits implementing the correction circuits described by reference to FIGS. 2-9 remains the same, having also started at near zero.

It should be noted that although the graph shows that the prior art and the correction circuit start at slightly different leakage current values, this is only to clearly show both lines. The graph should be interpreted as both lines starting at substantially the same leakage current value.

For example, in performed simulations, the current leakage in prior art circuits can be seen to reach close to 100 nA while current leakage in circuits implementing the correction circuit of the invention remains sub-nA. As such, it can be seen that current leakage is mitigated by the correction circuit, meaning that area-efficient, small, dense capacitors (that suffer from current leakage) may be used in circuits which would otherwise be negatively impacted by the current leakage in the form of reduced accuracy or the like.

Various improvements and modifications can be made to the above without departing from the scope of the disclosure.

1. A current leakage mitigation circuit comprising:
a charge storage circuit configured to receive a control signal output, wherein the control signal is output by an amplifier circuit connected to the current leakage mitigation circuit; and
a correction circuit connected to a bottom plate of the charge storage device;
wherein the correction circuit is configured to:
sample the control signal;
apply a filter to the control signal, wherein the filter is configured to extract a predefined frequency component;
amplify the filtered control signal; and
apply the amplified control signal to the bottom plate of the current storage device.

2. The circuit of claim 1, wherein the charge storage circuit comprises a capacitor.

3. The circuit of claim 2, wherein the correction circuit comprises:
a filter circuit configured to apply a filter to the control signal; and
a buffer amplifier connected to the charge storage circuit configured to amplify the filtered control signal and apply the amplified control signal to the bottom plate of the current storage device.

4. The circuit of claim 3, wherein the buffer amplifier is connected to a bottom plate of the capacitor of the charge storage circuit.

5. The circuit of claim 3, wherein the filtered control signal is amplified by the buffer amplifier by applying a gain value to the control signal.

6. The circuit of claim 5, wherein the gain value is a unity gain value or an arbitrary value.

7. The circuit of claim 3, wherein the filter circuit comprises a low-pass filter.

8. The circuit of claim 7, wherein the filter circuit comprises a resistor and a capacitor.

9. The circuit of claim 7, wherein the filter circuit comprises an amplifier device and a capacitor.

10. The circuit of claim 8, wherein the capacitor is connected between the output of the amplifier circuit and ground.

11. The circuit of claim 9, wherein the capacitor is connected between the output of the amplifier circuit and ground.

12. The circuit of claim 7, wherein the low-pass filter is one of a passive, active, or digital filter.

13. The circuit of claim 11, wherein the charge storage circuit comprises a plurality of capacitors.

14. The circuit of claim 13, wherein the capacitor and/or plurality of capacitors are thin oxide capacitors.

15. The circuit of claim 13, wherein the capacitor and/or the plurality of capacitors are thick oxide capacitors.

16. The circuit of claim 1, wherein the amplifier circuit comprises an amplifier device;
wherein the amplifier device is a transconductance amplifier, an EA amplifier, an error amplifier, or a GM amplifier.

17. The circuit of claim 1, wherein the circuit further comprises a PMOS or NMOS device configured to generate a fixed voltage to be applied to the charge storage circuit;
wherein the PMOS or NMOS device is connected to the correction circuit; and
wherein the correction circuit applies a fixed current to the PMOS or NMOS device.

18. The circuit of claim 1, wherein the circuit is part of a DC-DC converter.

19. The circuit of claim 2, wherein the charge storage circuit further comprises a resistor.

20. A method of mitigating current leakage in a circuit, the method comprising:
sampling, by a correction circuit, a control signal output by an amplifier circuit connected to the current leakage mitigation circuit,
applying, by the correction circuit, a filter to the control signal, wherein the filter is configured to extract a predefined frequency component of the control signal;
amplifying, by the correction circuit, the filtered control signal; and
applying, by the correction circuit, the amplified control signal to a charge storage circuit,
wherein the charge storage circuit is connected between the amplifier circuit and the correction circuit.
